(19) United States
(12) Patent Application Publication
(10) Pub. No.: US 2005/0133908 A1
(43) Pub. Date: Jun. 23, 2005

(54) Chip assembly with glue-strengthening holes

(75) Inventor: Tzung-Lung Lee, Hsi Chih City (TW)

Correspondence Address: TROXELL LAW OFFICE PLLC, SUITE 1404, 5205 LEESBURG PIKE, FALLS CHURCH, VA, 22041, US

(73) Assignee: Advanced Thermal Technologies

(21) Appl. No.: 10/737,906

(22) Filed: Dec. 18, 2003

(51) Int. Cl. H01L 23/34

(52) U.S. Cl. 257/718

(57) ABSTRACT

A chip assembly with glue-strengthening holes includes a substrate, a heat-dissipating plate and glue. A chip is arranged on the substrate. The heat-dissipating plate is made of a metal material. The heat-dissipating plate has a peripheral frame projected from a bottom thereof and a plurality of holes correspondingly formed on the peripheral frame. The heat-dissipating plate is covered on the chip. The glue is pasted between the peripheral frame of the heat-dissipating plate and the substrate, so that the glue is filled in the holes of the heat-dissipating plate for generating a griping strength.

### BACKGROUND OF THE INVENTION

1. Field of the Invention

The present invention relates to a chip assembly and, more particularly to a chip assembly with glue-strengthening holes for use in a semiconductor-packaging field, thereby to assist the chip cooled, and a heat-dissipating plate and a substrate can be securely combined as a heat-dissipating structure.

2. Description of the Related Art

Please referring to FIG. 1, a convention heat-dissipating structure for use in a semiconductor-packaging field, which includes a substrate 80 on which a chip 81 is arranged and a heat-dissipating plate 90 made of a metal material with the better heat conduction. The heat-dissipating plate 90 is covered on the chip 81 and the substrate 80. The heat-dissipating plate 90 has a peripheral frame 91 at its bottom. The peripheral frame 91 is securely pasted on the substrate 80 by glue 100. The heat-dissipating structure is contacted with the chip 81 through the heat-dissipating plate 90, thereby enabling the heat of the chip 81 to be guided out and to prevent the chip 81 from being damaged due to an external force.

However, the above heat-dissipating structure uses the glue 100 to paste the heat-dissipating plate 90 on the substrate 80, hence it will generate the worse combined strength. Because it is difficult to pass the experiment of the stretching test, it will be extremely trouble for operators.

Accordingly, the convention heat-dissipating structure has drawbacks in practical use. The present invention aims to resolve the above problems in the prior art.

### SUMMARY OF THE INVENTION

It is therefore a principal object of the invention to provide a chip assembly with glue-strengthening holes for use in a semiconductor-packaging field. Furthermore, the glue-strengthening holes will be filled through the glue for generating a griping strength, thereby to assist the chip cooled, and the heat-dissipating plate and the substrate can be securely combined together, accordingly.

To achieve the above object, the present invention provides a chip assembly with glue-strengthening holes. The chip assembly comprises a substrate, a heat-dissipating plate and glue. The heat-dissipating plate is made of a metal material, and the heat-dissipating plate has a peripheral frame projected from a bottom thereof and a plurality of holes correspondingly formed on the peripheral frame. The glue is pasted between the peripheral frame of the heat-dissipating plate and the substrate.

To provide a further understanding of the invention, the following detailed description illustrates embodiments and examples of the invention, this detailed description being provided only for illustration of the invention.

### BRIEF DESCRIPTION OF THE DRAWINGS

The drawings included herein provide a further understanding of the invention. A brief introduction of the drawings is as follows:

FIG. 1 is a cross-sectional view of a heat-dissipating structure of prior art;

FIG. 2 is an exploded perspective view of a first embodiment of the present invention;

FIG. 3 is a perspective view of a first embodiment of the present invention;

FIG. 4 is a cross-sectional view of a first embodiment of the present invention;

FIG. 5 is a cross-sectional view of a second embodiment of the present invention;

FIG. 6 is a cross-sectional view of a third embodiment of the present invention;

FIG. 7 is a cross-sectional view of a fourth embodiment of the present invention;

FIG. 8 is a perspective view of a heat-dissipating plate of a fifth embodiment of the present invention;

FIG. 9 is a cross-sectional view of the heat-dissipating plate of a sixth embodiment of the present invention;

FIG. 10 is a perspective view of the heat-dissipating plate of a seventh embodiment of the present invention;

FIG. 11 is a cross-sectional view of the seventh embodiment of the present invention;

FIG. 12 is a cross-sectional view of an eighth embodiment of the present invention;

FIG. 13 is a cross-sectional view of a ninth embodiment of the present invention.

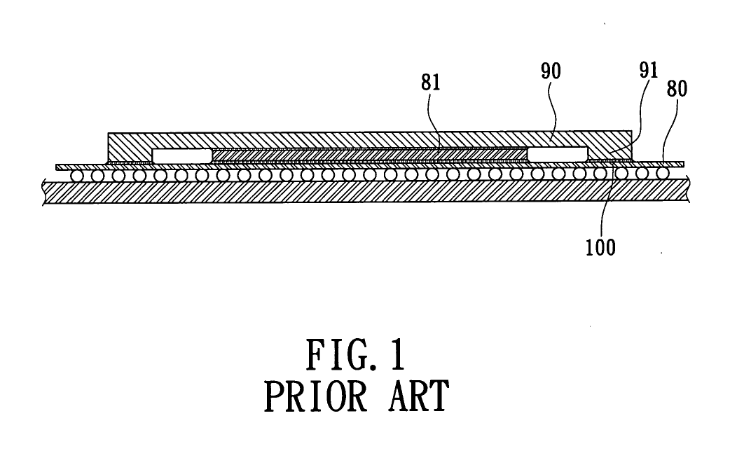

### DETAILED DESCRIPTION OF THE EMBODIMENTS

Wherever possible in the following description, like reference numerals will refer to like elements and parts unless otherwise illustrated.

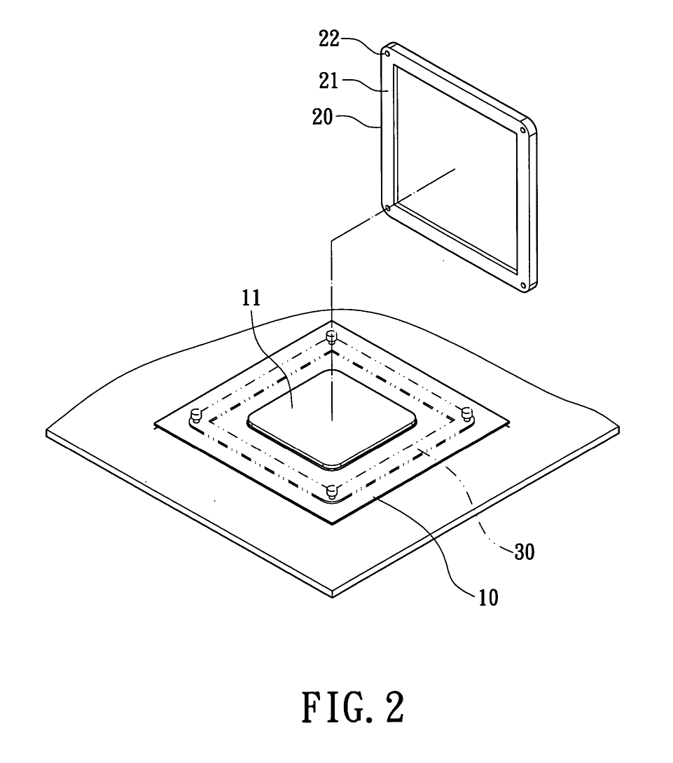

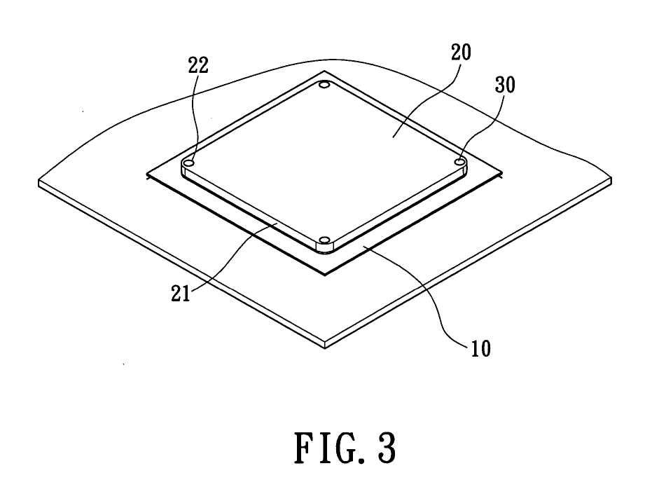

Referring to FIGS. 2-4, the present invention provides a chip assembly with glue-strengthening holes including a substrate 10 and a heat-dissipating plate 20. The substrate 10 is a square board on which a chip 11 is arranged.

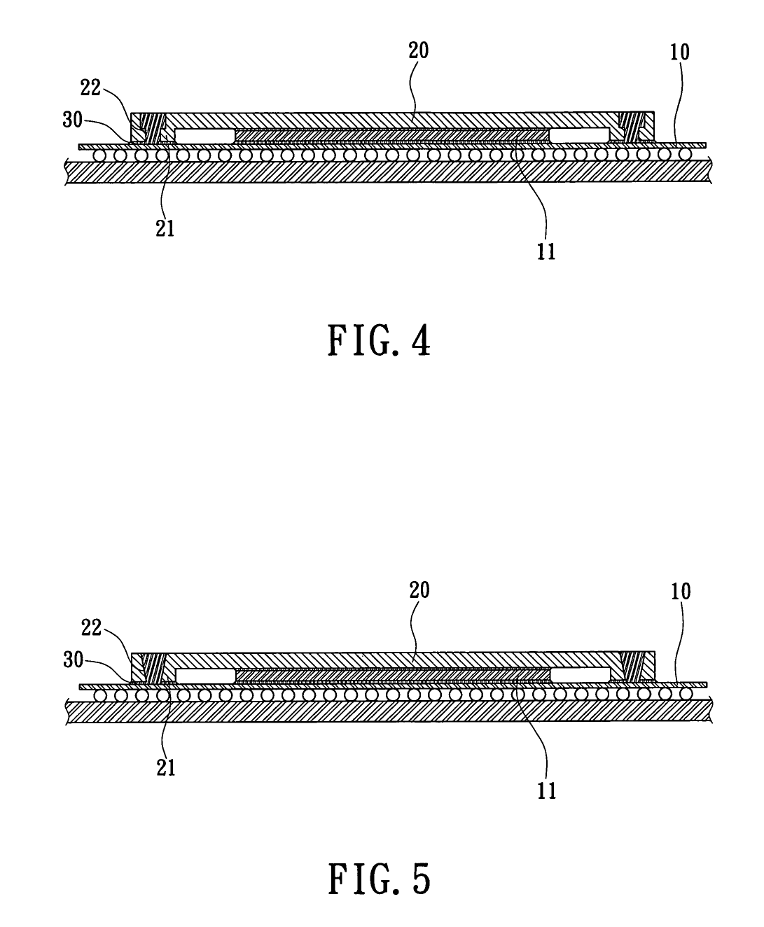

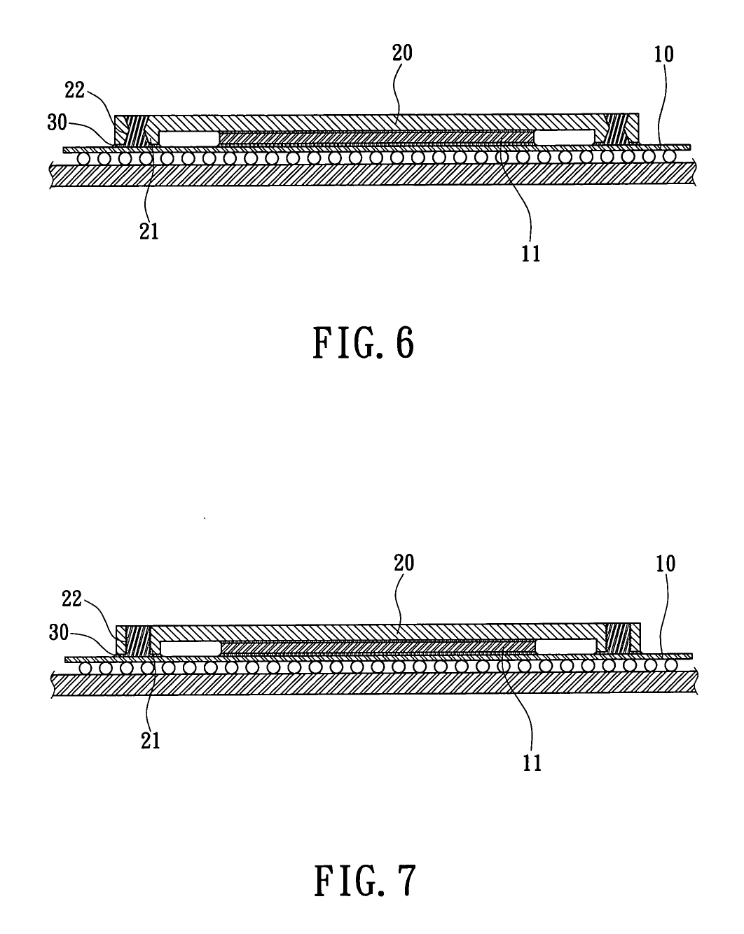

The heat-dissipating plate 20 is made of a metal material with the better heat conduction and can be a substantial square board. The heat-dissipating plate 20 has a peripheral frame 21 projected from its bottom. The peripheral frame 21 is surrounded on a circumference of the bottom of the heat-dissipating plate 20. The peripheral frame 21 is surrounded on a circumference of the bottom of the heat-dissipating plate 20. The heat-dissipating plate 20 has a plurality of holes 22 correspondingly formed on the peripheral frame 21. The holes 22 each are defined as a penetrating hole. The holes 22 each are defined as a T shaped hole (shown in FIG. 4), a cone hole (shown in FIG. 5), a sandglass shaped hole (shown in FIG. 6), or a screwed hole (shown in FIG. 7). The holes 22 each having a large upper opening and a small lower opening can increase the combined strength of the heat-dissipating plate 20 and the substrate 10.

When the heat-dissipating plate 20 will be combined with the substrate 10, the glue 30 is coated on a joint between the substrate 10 and the peripheral frame 21 of the heat-dissipating plate 20. Then the heat-dissipating plate 20 is covered on the chip 11 arranged on the substrate 10, so that the bottom surface of the peripheral frame 21 of the heat-dissipating plate 20 can be pasted on the substrate 10 by the glue 30. When the heat-dissipating plate 20 is pressed downwardly, the glue 30 between the heat-dissipating plate 20 and the substrate 10 is spilled into the holes 22. Furthermore, the glue 30 is filled in the holes 22 of the heat-dissipating plate 20 for generating a griping strength.

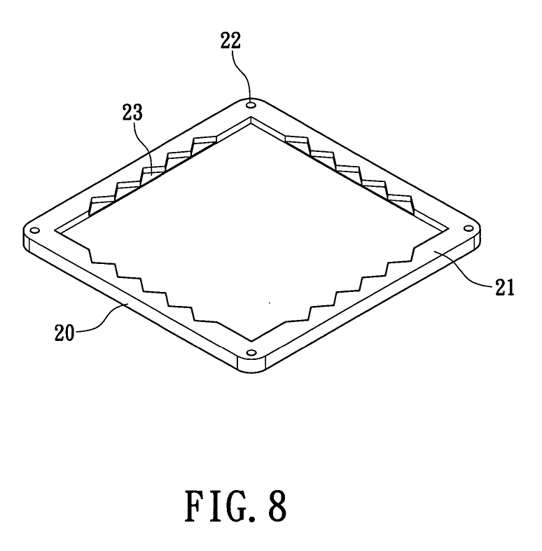

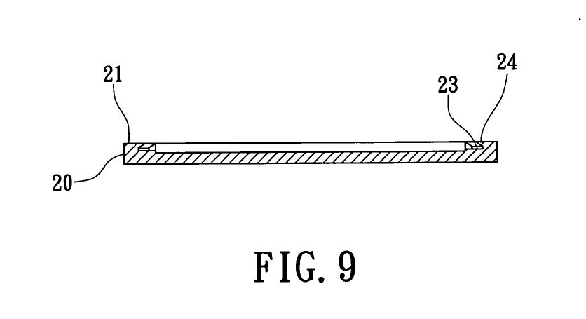

As shown in FIG. 8, the peripheral frame 21 of the heat-dissipating plate 20 has a plurality of tooth surfaces 23 formed on an inner wall thereof, and the tooth surfaces 23 each have a reversed angle 24 (shown in FIG. 9), so that the glue 30 is filled between the tooth surfaces 23 of the heat-dissipating plate 20 for generating a griping strength.

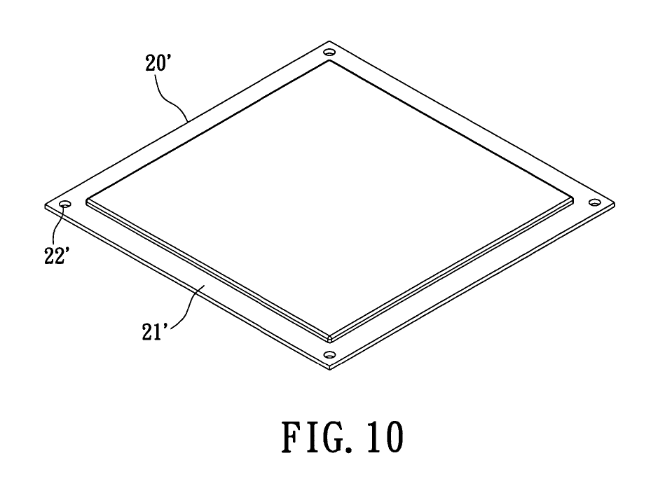

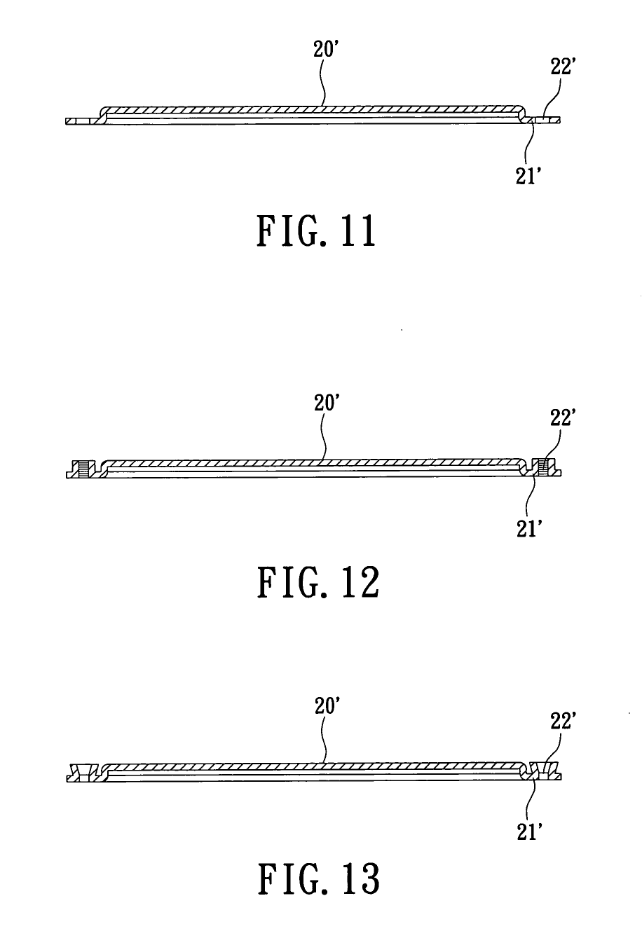

Additionally, as shown in FIG. 10, the peripheral frame 21′ is downwardly bent and horizontally extended from a peripheral of the heat-dissipating plate 20′. The holes 22′ are respectively distributed on four corners of the peripheral frame 21′. The holes 22′ each are defined as a penetrating hole (shown in FIG. 11), a screwed hole (shown in FIG. 12) and a trumpet shaped hole (shown in FIG. 13).

From the foregoing description, the chip assembly in accordance with the present invention has the following advantages:
1. By the heat-dissipating plate 20 contacted with the chip 11, the heat-dissipating plate 20 will guide out the heat of the chip 11 and assist the chip 11 cooled.
2. By the holes 22 arranged on the heat-dissipating plate 20, the glue 30 can spill into the holes 22 for generating a griping strength, and hence it will generate the better-combined strength between the heat-dissipating plate 20 and the substrate 10.

Furthermore, it will be able to pass the experiment of the stretching test, thereby to reduce defective fraction of the product.

Those skilled in the art will readily appreciate that the above description is only illustrative of specific embodiments and examples of the invention. The invention should therefore cover various modifications and variations made to the herein-described structure and operations of the invention, provided they fall within the scope of the invention as defined in the following appended claims.

1. A chip assembly, comprising:
a substrate;
a heat-dissipating plate made of a metal material, and the heat-dissipating plate having a peripheral frame projected from a bottom thereof and a plurality of holes correspondingly formed on the peripheral frame; and
a glue pasted between the frame of the heat-dissipating plate and the substrate, so that the glue is filled in the holes of the heat-dissipating plate for generating a griping strength.

2. The chip assembly of claim 1, wherein the heat-dissipating plate is covered on a chip arranged on the substrate.

3. The chip assembly of claim 1, wherein the peripheral frame is surrounded on a circumference of the bottom of the heat-dissipating plate.

4. The chip assembly of claim 1, wherein the holes each have a large upper opening and a small lower opening.

5. The chip assembly of claim 1, wherein the holes each are defined as a penetrating hole.

6. The chip assembly of claim 1, wherein the holes each are defined as a T shaped hole.

7. The chip assembly of claim 1, wherein the holes each are defined as a cone hole.

8. The chip assembly of claim 1, wherein the holes each are defined as a sandglass shaped hole.

9. The chip assembly of claim 1, wherein the holes each are defined as a screwed hole.

10. The chip assembly of claim 1, wherein the peripheral frame of the heat-dissipating plate has a plurality of tooth surfaces formed on an inner wall thereof, so that the glue is filled between the tooth surfaces of the heat-dissipating plate.

11. The chip assembly of claim 9, wherein the tooth surfaces each have a reversed angle.

12. A chip assembly, comprising:
a substrate;
a heat-dissipating plate made of a metal material, and the heat-dissipating plate having a peripheral frame downwardly bent and horizontally extended from a peripheral thereof and a plurality of holes correspondingly formed on the peripheral frame; and
a glue pasted between the frame of the heat-dissipating plate and the substrate, so that the glue is filled in the holes of the heat-dissipating plate for generating a griping strength.

13. The chip assembly of claim 12, wherein the holes are respectively distributed on four comers of the peripheral frame.

14. The chip assembly of claim 12, wherein the holes each are defined as a penetrating hole.

15. The chip assembly of claim 12, wherein the holes each are defined as a screwed hole.

16. The chip assembly of claim 12, wherein the holes each are defined as a trumpet shaped hole.
